(19) United States
(12) Patent Application Publication
(10) Pub. No.: US 2012/0153335 A1
(43) Pub. Date: Jun. 21, 2012

(54) SEMICONDUCTOR LIGHT-EMITTING DEVICE AND METHOD OF MANUFACTURING THE SAME

(75) Inventors: Koichi MATSUSHITA, Kanagawa-ken (JP); Muneaki Noguchi, Kanagawa-ken (JP); Hisashi Sogabe, Kanagawa-ken (JP); Hideyuki Mori, Fukuoka-ken (JP); Taihei Yamaguchi, Fukuoka-ken (JP)

(73) Assignee: KABUSHIKI KAISHA TOSHIBA, Tokyo (JP)

(21) Appl. No.: 13/332,974

(22) Filed: Dec. 21, 2011

(30) Foreign Application Priority Data
Dec. 21, 2010 (JP) 2010-284524

(51) Int. Cl. H01L 33/50

(52) U.S. Cl. 257/98; 438/27; 257/E33.061

(57) ABSTRACT

A semiconductor light-emitting device according to an embodiment includes a lead frame, an LED chip, a transparent resin, and a resin housing. The transparent resin coats the LED chip and the top surface of the lead frame. In addition, the transparent resin is filled in the space between the first lead frame and the second lead frame, and a part of the transparent resin is exposed to the bottom surface of the lead frame. The resin housing is provided over the lead frame. The resin housing includes an upper part coating a top surface of the transparent resin, side-surface parts coating side surfaces of the transparent resin, and an opening through which one of the side surfaces of the transparent resin is exposed.

### CROSS-REFERENCE TO RELATED APPLICATIONS

This application is based upon and claims the benefit of priority from the prior Japanese Patent Application No. 2010-284524, filed on Dec. 21, 2010; the entire contents of which are incorporated herein by reference.

### FIELD

Embodiments of the invention relate to a semiconductor light-emitting device and a method of manufacturing the semiconductor light-emitting device.

### BACKGROUND

A side-view type semiconductor light-emitting device is known which emits light through an opening formed in a portion of a side surface of the package encapsulating the light-emitting diode (LED) chip.

In general, a method of manufacturing a side-view type light-emitting device includes the steps of: mounting an LED chip in a hollow formed in a resin housing; wiring between the LED chip and a lead frame; and filling the hollow of the resin housing with a transparent resin or a resin containing a fluorescent material. Since all these steps need to be preformed through the opening formed in the side surface of the resin housing, this manufacturing method is poor workability.

To get a thin light-emitting device, the height of the opening formed in the side surface of the resin housing needs to be as low as possible. The narrowing of the opening, however, has a certain limit because the LED chip is mounted and wired in the hollow through the opening. This puts restraint on the thinning of the light-emitting device.

### BRIEF DESCRIPTION OF THE DRAWINGS

FIG. 1 is a schematic perspective view of a semiconductor light-emitting device of a first embodiment.

FIG. 2A is a schematic side view of the semiconductor light-emitting device of the first embodiment seen from the light-emitting surface side of the semiconductor light-emitting device. FIG. 2B is a schematic plan view of the device-mounting surface side of the semiconductor light-emitting device.

FIG. 3 is a schematic perspective view illustrating a lead frame and an LED chip included in the semiconductor light-emitting device of the first embodiment.

FIGS. 4A to 4D are schematic sectional views illustrating a method of manufacturing the semiconductor light-emitting device of the first embodiment.

FIGS. 5A to 5D are schematic sectional views illustrating a method of manufacturing the semiconductor light-emitting device of the first embodiment.

FIGS. 6A and 6B are schematic plan views illustrating an example of a two-dimensional pattern of a resin housing shown in FIG. 5A.

FIGS. 7A and 7B are schematic plan views illustrating another concrete example of the two-dimensional pattern of the resin housing.

FIGS. 8A and 8B are schematic plan views of a lead-frame sheet.

FIG. 9 is a schematic side view of a semiconductor light-emitting device of a second embodiment.

FIGS. 10A to 10C are schematic cross-sectional views illustrating a method of manufacturing the semiconductor light-emitting device of the second embodiment.

FIG. 11 is a schematic plan view illustrating an example of a two-dimensional pattern of a mold shown in FIG. 10A.

### DETAILED DESCRIPTION

A semiconductor light-emitting device provided according to an embodiment includes a lead frame, a light-emitting element, a transparent resin, and a resin housing.

The lead frame includes a first lead frame and a second lead frame, which are placed on a single plane and are separated from each other.

The light-emitting element is mounted on a top surface of the lead frame, and includes a first terminal connected to the first lead frame and a second terminal connected to the second lead frame.

The transparent resin coats both the light-emitting element and the top surface of the lead frame. The transparent resin also fills in the space between the first lead frame and the second lead frame. A part of the transparent resin is exposed to the bottom surface of the lead frame.

The resin housing is provided on the lead frame, and includes an upper portion that covers a top surface of the transparent resin, side-surface portions that cover side surfaces of the transparent resin, and an opening through which a part of one of the side surfaces of the transparent resin is exposed to the outside.

Embodiments of the invention will be described below by referring to the drawings. If a member appears in various drawings, the member is denoted by the same reference numeral.

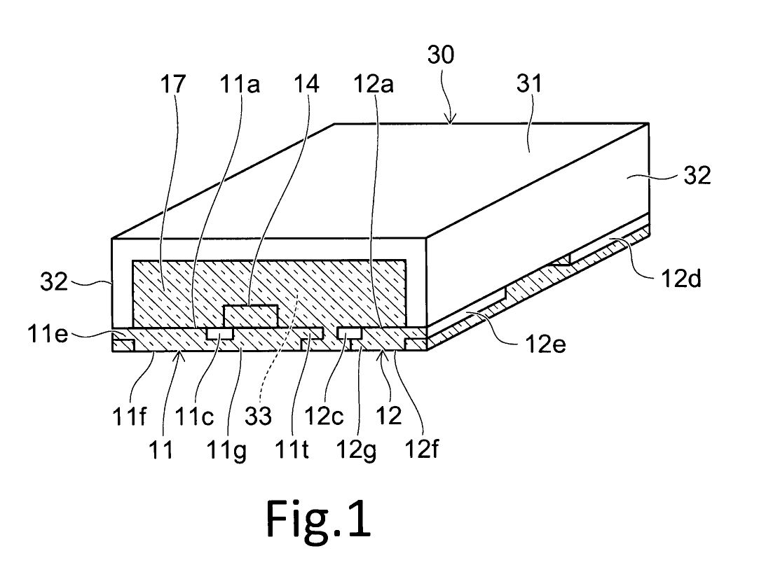

FIG. 1 is a schematic perspective view of a semiconductor light-emitting device of this embodiment.

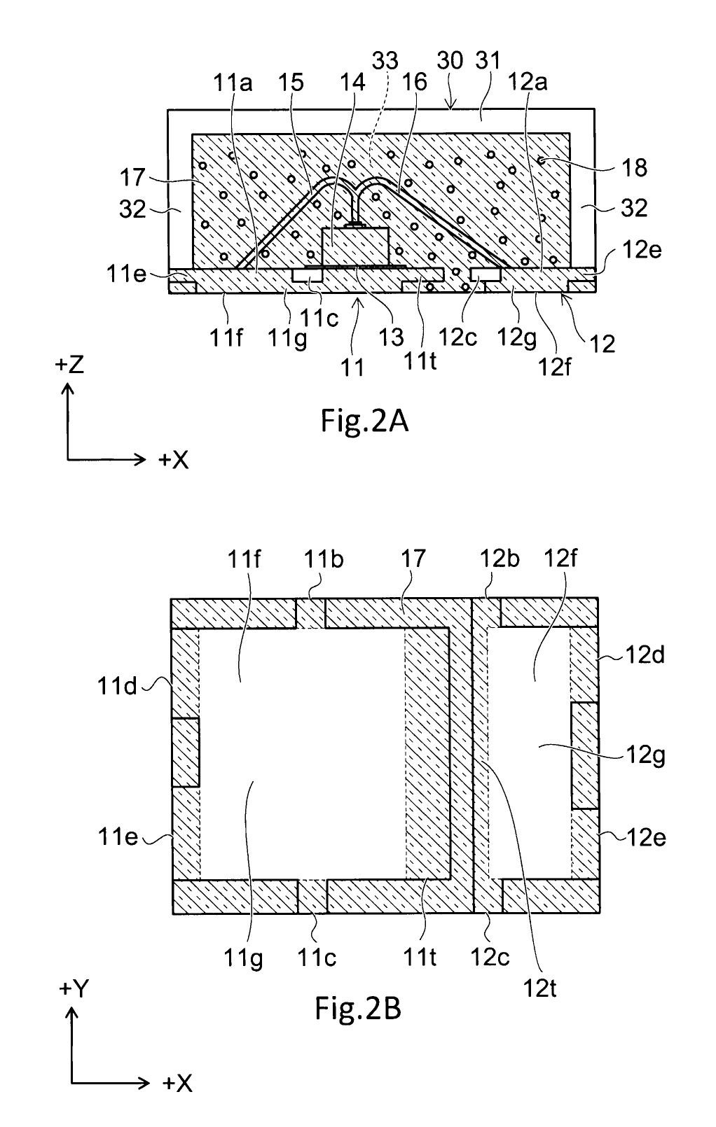

FIG. 2A is a schematic side view of the semiconductor light-emitting device of this embodiment seen from the light-emitting surface side of the semiconductor light-emitting device. FIG. 2B is a bottom view of the device-mounting surface side shown in FIG. 2A.

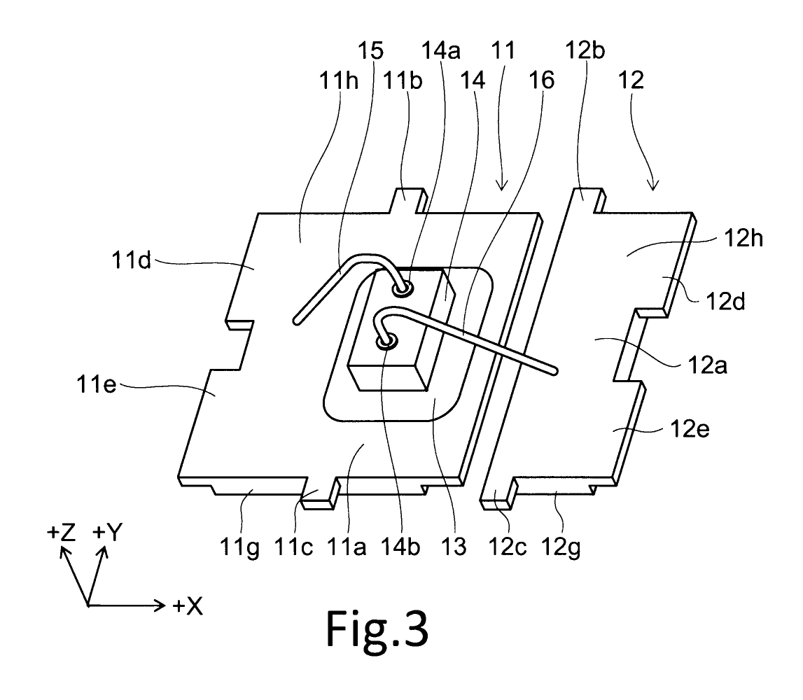

FIG. 3 is a schematic perspective view of the semiconductor light-emitting device of this embodiment, from which the resin housing and the transparent resin are removed.

A semiconductor light-emitting device of this embodiment includes a first lead frame (hereinafter, also referred to simply as a “lead frame”) 11 and a second lead frame (hereinafter, also referred to simply as a “lead frame”) 12.

The lead frame 11 and the lead frame 12 are placed on a single plane, and are separated from each other. Both the lead frame 11 and the lead frame 12 have flat-plate shapes. Both the lead frame 11 and the lead frame 12 are made of the same conductive material, and have, for example, a structure where a silver-plated layer is formed on both the top surface and the bottom surface of a copper plate. No silver-plated layer is formed on any of the end surfaces of the lead frame 11 or on any of those of the lead frame 12. The copper plate is exposed in each of the end surfaces.

For the sake of descriptive convenience, the XYZ orthogonal coordinate system is used in the description of this specification.

The +X direction denotes one of directions parallel to the top surfaces of the lead frame 11 and the lead frame 12, i.e., the direction from the lead frame 11 towards the lead frame 12.

The +Z direction denotes one of directions perpendicular to the top surfaces of the lead frame 11 and the lead frame 12, i.e., the upward direction (the direction towards an LED chip 14 mounted on the top surfaces).

The +Y direction denotes one of directions orthogonal to both the +X direction and the +Z direction.

Here, the −X direction, the −Y direction and the −Y direction denote the opposite directions to the +X direction, the +Y direction, and the −Z direction, respectively. In addition, “the X direction” is a simple and generic term to indicate both “the +X direction” and “the −X direction.”

The lead frame 11 includes a base portion 11a, which has a rectangular shape when seen in the Z direction. For example, four hanger pins 11b, 11c, 11d, 11e extend from the base portion 11a.

The hanger pin 11b extends in the +Y direction from a central part, in the X direction, of an end edge of the base portion 11a facing in the +Y direction. The hanger pin 11c extends in the −Y direction from a central part, in the X direction, of an edge of the base portion 11a facing in the −Y direction. The position, in the X direction, of the hanger pin 11b is the same as the position, in the X direction of the hanger pin 11c. The hanger pin 11d and the hanger pin 11e extend in the −X direction from the respective two end part, in the Y direction, of an edge of the base portion 11a facing in the −X direction. The four hanger pins 11b to 11e extend from three different sides of the base portion 11a.

The lead frame 12 has a shorter length in the X direction than the lead frame 11 but has the same length in the Y direction as does the lead frame 11. The lead frame 12 includes a base portion 12a having a rectangular shape when seen in the Z direction. For example, four hanger pins 12b, 12c, 12d, 12e extend from the base portion 12a.

The hanger pin 12b extends in the +Y direction from an end part, at the side of the lead frame 11, of the end edge of the base portion 12a facing in the +Y direction. The hanger pin 12c extends in the −Y direction from an end part, at the side of the lead frame 11, of the end edge of the base portion 12a facing in the −Y direction. The hanger pin 12d and the hanger pin 12e extend in the +X direction from the respective two end portions, in the Y direction, of the end edge of the base portion 12a facing in the +X direction. The four hanger pins 12b to 12e extend from three different sides of the base portion 12a.

The hanger pins 11d and 11e of the lead frame 11 may have widths in Y direction equal to or different from the widths in the Y direction of the hanger pins 12d and 12e of the lead frame 12. If the widths of the hanger pins 11d and 11e are different from the widths of the hanger pins 12d and 12e, it is easier to distinguish the anode and the cathode from each other.

A protruding area 11g is formed in a central part, in the X direction, of the base portion 11a in a bottom surface 11f of the lead frame 11. Consequently, the lead frame 11 has two different thicknesses. The central part, in the X direction, of the base portion 11a where the protruding area 11g is formed is thicker, while the two end parts, in the X direction, of the base portion 11a and the hanger pins 11b to 11e are thinner. In FIGS. 2A and 2B, the part of the base portion 11a where the protruding area 11g is not formed is referred to as a thin plate portion 11t.

Similarly, a protruding area 12g is formed in a central part, in the X direction, of the base portion 12a in a bottom surface 12f of the lead frame 12. Consequently, the lead frame 12 has two different thicknesses as well. The central part, in the X direction, of the base portion 12a is thicker because the protruding area 11g is formed there, while the two end parts, in the X direction, of the base portion 12a and the hanger pins 12b to 12e are thinner. In FIG. 2B, the part of the base portion 12a where the protruding area 12g is not formed is referred to as a thin plate portion 12t.

A cutaway part extending in the Y direction along an end edge of the base portion 11a is formed in the bottom surfaces of the respective two end parts, in the X direction, of the base portion 11a, while a cutaway part extending in the Y direction along an end edge of the base portion 12a is formed in the bottom surfaces of the respective two end parts, in the X direction, of the base portion 12a.

Within the lead frame 11, the protruding area 11g is formed in an area that is separated from the end edge facing the lead frame 12, and an area including the end edge constitutes the thin plate portion 11t. Within the lead frame 12, the protruding area 12g is formed in an area that is separated from the end edge facing the lead frame 11, and an area including the edge constitutes the thin plate portion 12t.

The top surface of the lead frame 11 and the top surface of the lead frame 12 are on the same plane, while the bottom surface 11f of the protruding area 11g of the lead frame 11 and the bottom surface 12f of the protruding area 12g of the lead frame 12 are on the same plane. The position, in the Z direction, of the top surface of each hanger pin coincides with the corresponding positions of the top surfaces of the lead frame 11 and the lead frame 12. Hence, all the hanger pins are arranged on the same XY plane.

A die-mounting material 13 is provided to a part of an area corresponding to the base portion 11a in the top surface of the lead frame 11. The die-mounting material 13 may be electrically conductive or electrically insulating. For example, silver paste, solder or the like may be used as the conductive die-mounting material 13. For example, transparent-resin paste may be used as the insulating die-mounting material 13.

The LED (Light Emitting Diode) chip 14 is provided on the die-mounting material 13. The LED chip 14 is bonded to the top surface of the lead frame 11 by means of the die-mounting material 13.

The LED chip 14 has a structure where, for example, a semiconductor layer containing gallium nitride (GaN) or the like is stacked on a sapphire substrate. The LED chip 14 has, for example, a shape of rectangular parallelepiped. Terminals 14a, 14b (see FIG. 3) are provided on the top surface of the LED chip 14. When a voltage is supplied between the terminal 14a and the terminal 14b, the LED chip 14 emits light of a blue color, for example.

A first end of a wire 15 is connected to the terminal 14a of the LED chip 14. The wire 15 is drawn out from the terminal 14a in the +Z direction (in the straight upward direction), and is then curved in a direction between the −X direction and the −Z direction. A second end of the wire 15 is bonded to the top surface of the lead frame 11. Thus, the terminal 14a is connected to the lead frame 11 via the wire 15.

On the other hand, a first end of a wire 16 is connected to the terminal 14b of the LED chip 14. The wire 16 is drawn out from the terminal 14b in the +Z direction, and is then curved in a direction between the +X direction and the −Z direction. A second end of the wire 16 is bonded to the top surface of the lead frame 12. Thus, the terminal 14b is connected to the lead frame 12 via the wire 16. The wires 15 and 16 are made of a metal such as gold or aluminum.

A resin housing 30 is provided on the top surfaces of the lead frame 11 and the lead frame 12. The resin housing 30 has a hollow, which is filled with a transparent resin 17.

The transparent resin 17 is transparent to the light emitted from the LED chip 14. For example, a silicone resin may be used as the transparent resin 17.

The transparent resin 17 coats the top surface of the lead frame 11, the top surface of the lead frame 12, the LED chip 14, the wire 15 and the wire 16. In addition, the transparent resin 17 fills the space between the lead frame 11 and the lead frame 12.

The bottom surface 11f of the protruding area 11g of the lead frame 11 and the bottom surface 12f of the protruding area 12g of the lead frame 12 are not coated with the transparent resin 17, and are thus exposed. The bottom surfaces of the lead frame 11 and the lead frame 12, except the bottom surfaces 11f and 12f, are coated with the transparent resin 17.

To put it differently, parts of the transparent resin 17 are exposed to the bottom surfaces of the lead frame 11 and the lead frame 12, respectively. The parts of the transparent resin 17 exposed to the bottom surfaces are hatched in FIG. 2B. The bottom surfaces 11f, 12f corresponding to the areas that are not hatched in FIG. 2B are exposed without being coated with the transparent resin 17. The bottom surfaces 11f, 12f serve as external electrode pads that are to be used when the semiconductor light-emitting device is mounted on a circuit board or the like. The bottom surfaces 11f, 12f are on the same plane as is the bottom surface of the transparent resin 17 exposed to the bottom surfaces of the lead frame 11 and the lead frame 12.

The leading-end surfaces of the hanger pins 11b to 11e, 12b to 12e are exposed without being coated with the transparent resin 17. The top surfaces, the bottom surfaces, and the side surfaces of the hanger pins 11b to 11e, 12b to 12e are coated with the transparent resin 17.

The periphery of the base portion 11a of the lead frame 11 (including the end surfaces of the thin plate portion 11t) and the periphery of the protruding area 11g are coated with the transparent resin 17. The periphery of the base portion 12a of the lead frame 12 (including the end surfaces of the thin plate portion 12t) and the periphery of the protruding area 12g are coated with the transparent resin 17. The bottom surface of the thin plate portion 11t of the lead frame 11 and the bottom surface of the thin plate portion 12t of the lead frame 12 are coated with the transparent resin 17.

When seen from above the LED chip 14, the transparent resin 17 has a quadrangular shape (e.g., a rectangular shape). The leading-end surfaces of the hanger pins 11b to 11e of the lead frame 11 are exposed to three different side surfaces of the transparent resin 17. The leading-end surfaces of the hanger pins 12b to 12e of the lead frame 12 are exposed to three different side surfaces of the transparent resin 17.

In all the side surfaces below the resin housing 30, only the leading-end surfaces of the hanger pins 11b to 11e, 12b to 12e are exposed from the transparent resin 17. In addition, in the bottom surfaces of the lead frame 11 and the lead frame 12, only the bottom surface 11f of the protruding area 11g and the bottom surface 12f of the protruding area 12g are exposed from the transparent resin 17.

The resin housing 30 coats the top surface and three side surfaces of the transparent resin 17. The resin housing 30 includes an upper portion 31 that coats the top surface of the transparent resin 17, side-surface portions 32 that coat the side surfaces of the transparent resin 17, and an opening 33 through which one of the side surfaces of the transparent resin 17 is exposed. Though not illustrated in FIG. 1 or FIG. 2A, a side surface of the transparent resin 17, which is opposed to the opening 33, is also coated with one of the side-surface portions 32 of the resin housing 30. The upper portion 31 and the side-surface portions 32 of the resin housing 30 have the light blocking property or the light reflecting property with respect to the light produced in the inside of the resin housing 30.

In the resin housing 30, at least the internal walls have the light reflecting property with respect to the light emitted by the LED chip 14. If the transparent resin 17 contains a fluorescent material, the internal walls of the resin housing 30 function, too, as a reflecting material for the light emitted from the fluorescent material. Thus, the light generated in the inside of the resin housing 30 can be guided to the opening 33 efficiently. For example, a polyamide white resin may be used as the resin housing 30.

As FIG. 2A shows, a large number of fluorescent bodies 18 may be dispersedly contained in the transparent resin 17. The transparent resin 17 is transparent to light emitted from the fluorescent bodies 18. The fluorescent bodies 18 are granular. The fluorescent bodies 18 absorb the light emitted by the LED chip 14, and emit light with longer wavelengths. For example, the fluorescent bodies 18 absorb part of the blue light emitted by the LED chip 14, and emit yellow light.

Hence, for example, white light is discharged through the opening 33 of the resin housing 30 as mixed light of the blue light, which is emitted by the LED chip 14 but not absorbed by the fluorescent bodies 18, and the yellow light emitted by the fluorescent bodies 18. Incidentally, if the LED chip 14 has a structure to emit light from the side surface, the light can be efficiently discharged to the outside through the opening 33.

A silicate fluorescent material that emits light of a yellow-green color, a yellow color, or an orange color may be used for the fluorescent bodies 18. The silicate fluorescent material can be expressed with the following general formula.

(2-x-y)SrO.x(Baᵤ,Caᵥ)O.(1-a-b-c-d)SiO₂.aP₂O₅bAl₂O₃cB₂O₃dGeO₂:yEu²⁺

where 0<x, 0.005<y<0.5, x+y≦1.6, 0≦a, b, c, d<0.5, 0<u, 0<v, and u+v=1.

A YAG fluorescent material may be used as the yellow-color fluorescent material. The YAG fluorescent material can be expressed with the following general formula.

(RE₁₋ₓSmₓ)₃(Al_{y}Ga_{1-y})₅O₁₂:Ce

where 0≦x≦1, 0≦y≦1, RE is at least one element selected from a group consisting of Y and Gd.

A mixture of a sialon red-color fluorescent material and a sialon green-color fluorescent material may be used for the fluorescent bodies 18. That is to say, the fluorescent bodies 18 may contain: the green-color fluorescent material that absorbs the blue light emitted by the LED chip 14 and emits green light; or the red-color fluorescent material that absorbs the blue light emitted by the LED chip 14 and emit red light.

The sialon red-color fluorescent material can be expressed with the following general formula.

(M₁₋ₓRₓ)ₐ₁AlSi_{b1}O_{c1}N_{d1}

where: M denotes at least one of metal elements except Si and Al, and is preferably at least one of Ca and Sr; R denotes a luminescent center element, and is preferably Eu; and x, a1, b1, c1, and d1 are determined in a way that 0<x≦1, 0.6<a1<0.95, 2<b1<3.9, 0.25<c1<0.45, 4<d1<5.7.

A specific example of such a sialon red-color fluorescent material is shown below.

Sr₂Si₇Al₇ON₁₃:Eu²⁺

The sialon green-color fluorescent material can be expressed with the following general formula.

(M₁₋ₓRₓ)ₐ₂AlSi_{b2}O_{c2}N_{d2}

where: M denotes at least one of metal elements except Si and Al, and is preferably at least one of Ca and Sr; R denotes a luminescent center element, and is preferably Eu; and x, a2, b2, c2, and d2 are determined in a way that 0<x≦1, 0.93<a2<1.3, 4.0<b2<5.8, 0.6<c2<1, 6<d2<11.

A specific example of such a sialon green-color fluorescent material is shown below.

Sr₃Si₁₃Al₃O₂N₂₁:Eu²⁺

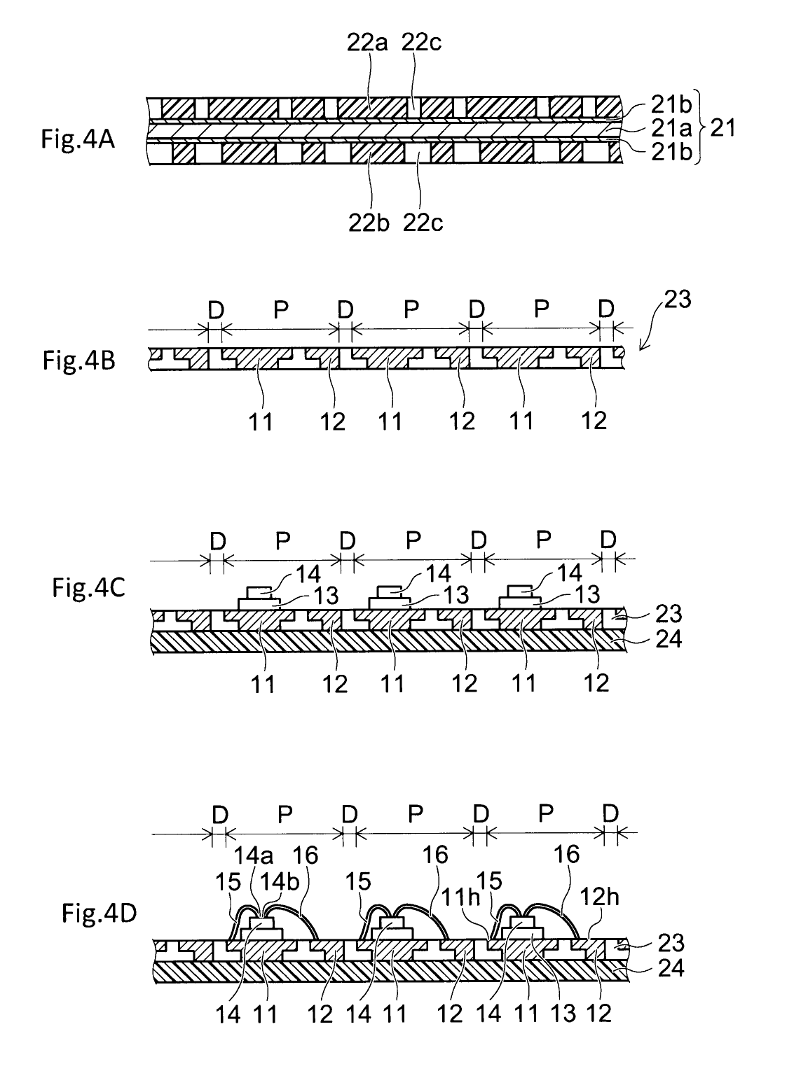

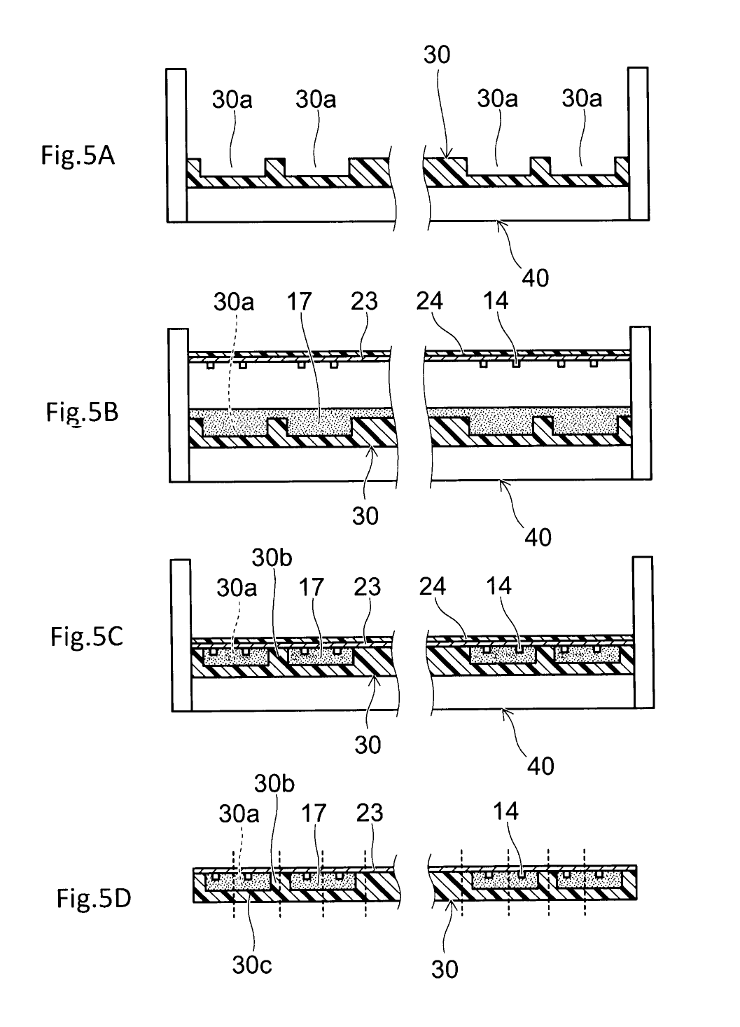

Next, description will be given below of a method of manufacturing the semiconductor light-emitting device of this embodiment. FIG. 4A to FIG. 5D are schematic cross-sectional views illustrating the method of manufacturing the semiconductor light-emitting device of this embodiment.

FIGS. 4A and 4B show a method of forming a lead-frame sheet 23 including multiple sets each consisting of the lead frame 11 and the lead frame 12.

The lead-frame sheet 23 is obtained by processing a conductive sheet 21 shown in FIG. 4A. The conductive sheet 21 is that in which silver-plated layers 21b are formed respectively on both the top surface and the bottom surface of a strip-shaped copper plate 21a.

A mask 22a is provided on the top surface of the conductive sheet 21 while a mask 22b is provided on the bottom surface of the conductive sheet 21. Openings 22c are selectively formed both in the mask 22a and in the mask 22b. The mask 22a and the mask 22b may be formed, for example, by printing.

Then, the conductive sheet 21 provided with the mask 22a and the mask 22b is dipped in an etchant to wet-etch the conductive sheet 21. Thus, of the conductive sheet 21, the portions located in the openings 22c are etched and selectively removed.

During the wet-etching, the amount of etching is controlled by, for example, adjusting the dipping time. By such control, the etching process is stopped before neither etching from the top-surface side of the conductive sheet 21 nor the etching from the bottom-surface side of the conductive sheet 21 penetrate the conductive sheet 21 solely. That is to say, half-etching is done both from the top-surface side and from the bottom-surface side. Note that portions of the conductive sheet 21, which are etched both from the top-surface side and from the bottom-surface side, are made to penetrate the conductive sheet 21. Thereafter, the mask 22a and the mask 22b are removed.

Thus, as FIG. 4B shows, the copper plate 21a and the silver-plated layers 21b are selectively removed from the conductive sheet 21, and thereby the lead-frame sheet 23 is formed. For the sake of illustrative convenience, in FIG. 4B and the ensuing drawings, the copper plate 21a and the silver-plated layers 21b are illustrated unitarily as the lead-frame sheet 23 while not distinguished from one another.

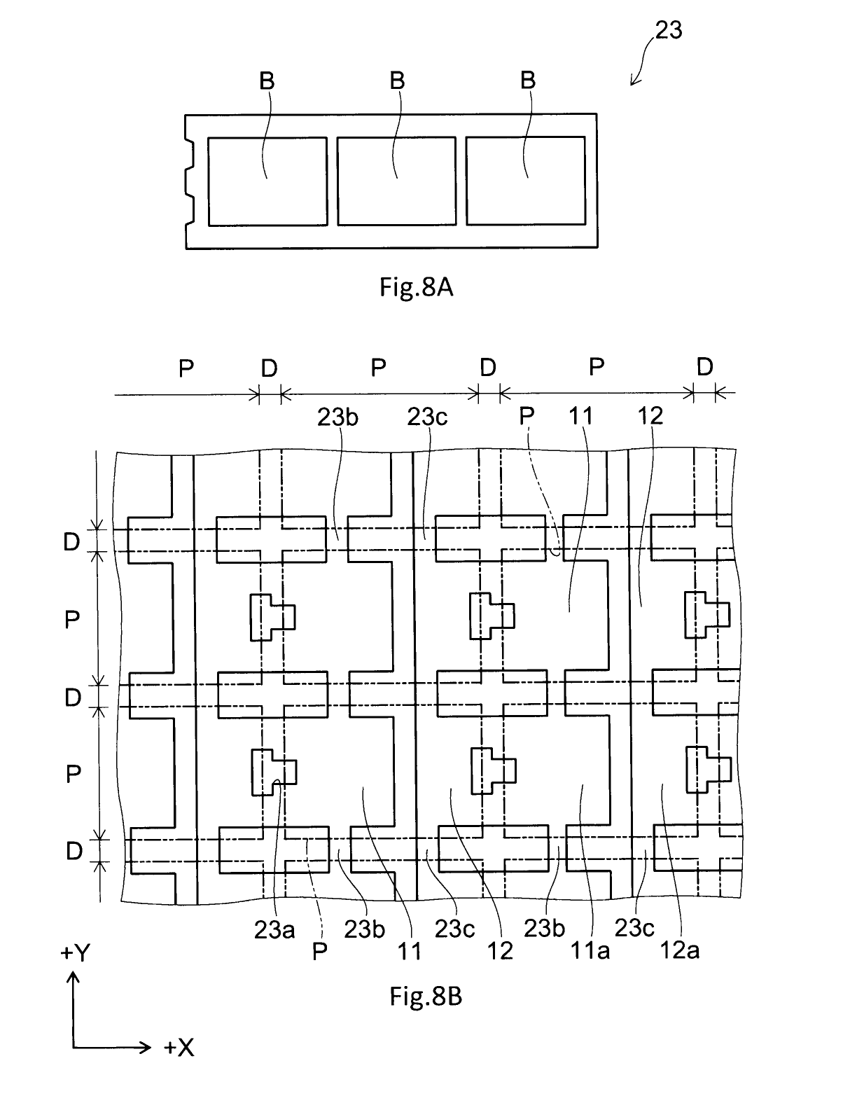

FIG. 8A is a plan view of the lead-frame sheet 23. FIG. 8B is a partially enlarged plan view of element regions P of the lead-frame sheet 23.

As FIG. 8A shows, for example, three blocks B are set in the lead-frame sheet 23. For example, approximately a thousand element regions P are set in each block B.

As FIG. 8B shows, the element regions P are arranged in a matrix shape. A lattice-shaped dicing regions D are formed between adjacent element regions P. A basic pattern including the lead frame 11 and the lead frame 12 that are separated from each other is formed in each element region P. The conductive material, of which the conductive sheet 21 is made, remains in the dicing regions D in a way that makes adjacent element regions P connected together.

To put it differently, the lead frame 11 and the lead frame 12 included in each single element region P are separated from each other. However, the lead frame 11 belonging to each element region P is connected to the lead frame 12 belonging to an element region P that is located adjacent to the element region P in the −X-direction. An opening 23a whose plan shape facing in the +X direction has a protruding shape is between the two frames.

The lead frames 11, respectively, belonging to each two adjacent element regions P in the Y direction are connected to each other via a bridge 23b. Similarly, the lead frames 12, respectively, belonging to each two adjacent element regions P in the Y direction are connected to each other via a bridge 23c. Accordingly, four conductive members extend in three directions from each of the base portion 11a of the lead frame 11 and the base portion 12a of the lead frame 12.

In addition, the etching from the bottom surface of the lead-frame sheet 23 is performed by half-etching, so that the above-described protruding areas 11g and 12g are formed in the bottom surfaces of the lead frame 11 and the lead frame 12, respectively.

Then, as FIG. 4C shows, as a supporting body, a reinforcement tape 24 made, for example, of polyimide is applied to the bottom surface of the lead-frame sheet 23. Subsequently, die-mounting materials 13 are supplied respectively onto the lead frames 11 that belong to the element regions P of the lead-frame sheet 23. For example, paste of the die-mounting material 13 may be ejected onto the lead frames 11 from an ejector, or transferred onto the lead frames 11 by using some mechanical means.

Afterward, the LED chip 14 is mounted on top of the die-mounting material 13, and heat treatment is performed to harden the die-mounting material 13. Thus, the LED chip 14 is mounted, by means of the die-mounting material 13, on the lead frame 11 of each element region P of the lead-frame sheet 23.

Thereafter, as FIG. 4D shows, the first end of the wire 15 is bonded to the terminal 14a of the LED chip 14 by, for example, the ultrasonic bonding method while the second end of the wire 15 is bonded to the top surface of the lead frame 11. On the other hand, the first end of the wire 16 is bonded to the terminal 14b of the LED chip 14 while the second end of the wire 16 is bonded to the top surface 12h of the lead frame 12. Thus, the terminal 14a is connected to the lead frame 11 via the wire 15 while the terminal 14b is connected to the lead frame 12 via the wire 16

FIGS. 5A to 5D show a process of providing the transparent resin 17 and the resin housing 30 to the lead-frame sheet 23 and a dicing process.

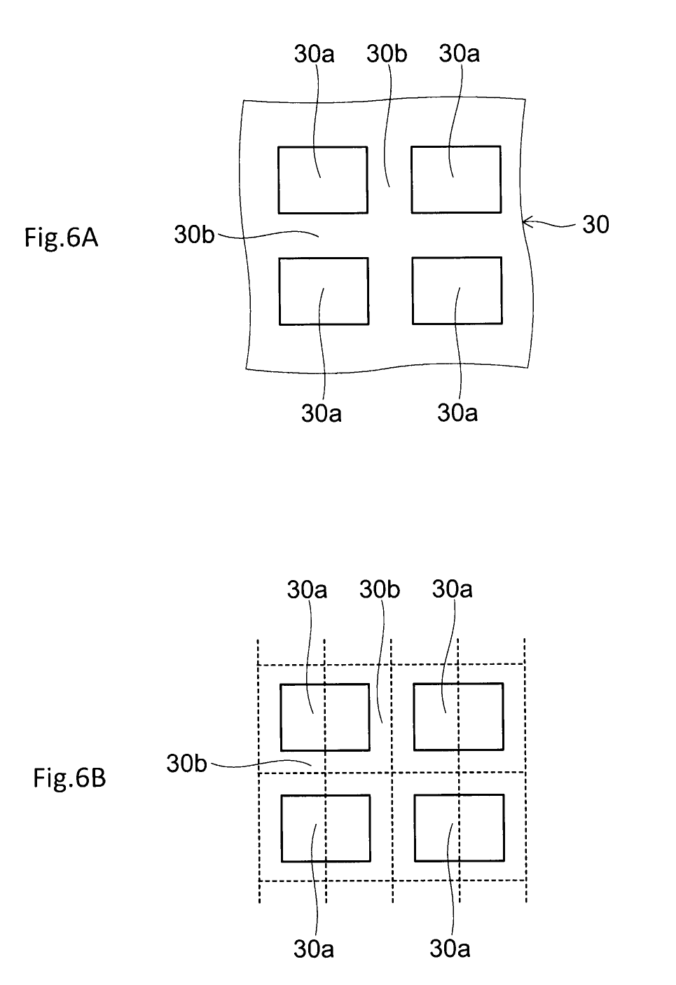

FIG. 5A shows a state where the resin housing 30 is set in a mold 40. The resin housing 30 is formed in a shape having multiple recessed portions 30a by, for example, the injection molding method. As the top-surface diagram shown in FIG. 6A illustrates, the recessed portions 30a are arranged in a matrix shape. Wall portions 30b exist between adjacent recessed portions 30a, for example, in a lattice-shaped two-dimensional pattern. The resin housing 30 is set in the mold 40 with the recessed portions 30a facing upwards.

As FIG. 5B shows, the transparent resin 17 that is in an uncured state, such as in a liquid state or in a gel state, is supplied to the recessed portions 30a of the resin housing 30. For example, the liquid or gel transparent resin 17 containing the fluorescent material is prepared by mixing and agitating the fluorescent material with a transparent resin such as a silicone resin. The transparent resin 17 is also supplied onto the top surfaces of the portions located between adjacent recessed portions 30a of the resin housing 30.

Next, as FIG. 5B shows, the lead-frame sheet 23 with the LED chips 14 mounted on it are set above the transparent resin 17 and the resin housing 30 within the mold 40. The lead-frame sheet 23 faces its surface, on which the LED chips 14 are mounted, toward the transparent resin 17 and the resin housing 30 located underneath. The reinforcement tape 24 is applied to the back surface of the lead-frame sheet 23, which is opposite from the surface on which the LED chips 14 are mounted.

Subsequently, as FIG. 5C shows, the lead-frame sheet 23 is lowered, as well as is dipped in and pressed against the transparent resin 17. The LED chips 14 are set in the recessed portions 30a of the resin housing 30, and the transparent resin 17 coats the LED chips 14, the wires 15, the wires 16, and the front surface of the lead-frame sheet 23 (specifically, the surface where the LED chips 14 are mounted). Multiple LED chips 14 (in the illustrated case, for, example, two LED chips 14) are set in each single recessed portion 30a.

At this moment, the transparent resin 17 is filled, too, into the portions in the lead-frame sheet 23 that have been removed by the etching. As the reinforcement tape 24 is applied to the back surface of the lead-frame sheet 23, the transparent resin 17 does not leak out to the back surface of the lead-frame sheet 23. Accordingly, none of the bottom surfaces 11f of the protruding areas 11g of the lead frames 11 and none of the bottom surfaces 12f of the protruding areas 12g of the lead frames 12 are coated with the transparent resin 17.

Then, the transparent resin 17 is hardened with the lead-frame sheet 23 pressed onto the transparent resin 17. Thus, the transparent resin 17 is compression-molded. The transparent resin 17 is hardened by, for example, heat. The top surfaces of the wall portions 30b located between the adjacent recessed portions 30a of the resin housing 30 are bonded to the surface of the lead-frame sheet 23. Consequently, the lead-frame sheet 23, the transparent resin 17, and the resin housing 30 are united together.

Thereafter, the united body of the lead-frame sheet 23, the transparent resin 17 and the resin housing 30 is taken out of the mold 40. Subsequently, the reinforcement tape 24 is peeled off. Thus, the bottom surfaces 11f of the protruding areas 11g of the lead frames 11 and the bottom surfaces 12f of the protruding areas 12g of the lead frames 12 are exposed to the back surface of the lead-frame sheet 23.

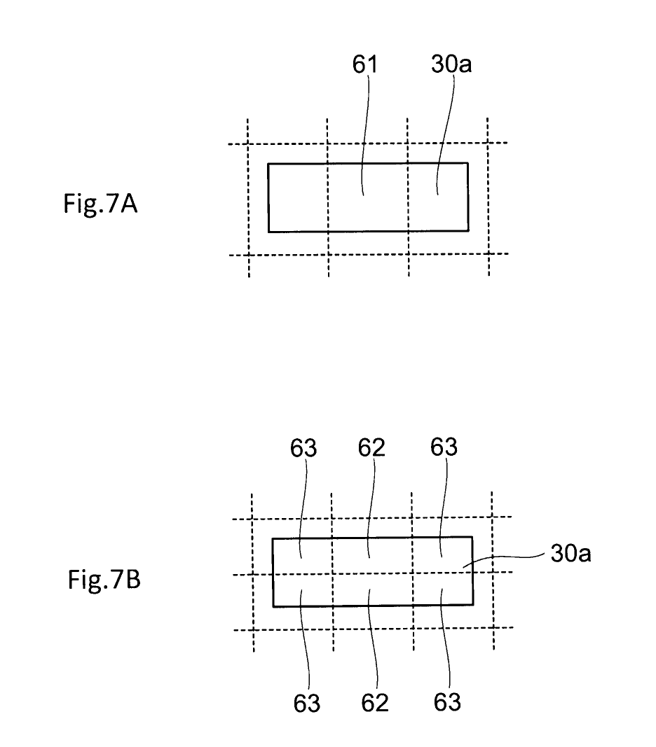

Afterward, the lead-frame sheet 23, transparent resin 17 and the resin housing 30 are cut by using, for example, blades. The cutting is done along the dashed lines shown in FIG. 5D. In FIG. 6B, the cutting positions seen from above are indicated with dashed lines. In FIGS. 7A and 7B, too, the cutting positions seen from above are indicated with dashed lines.

Specifically, in the resin housing 30, the wall portions 30b around each recessed portion 30a, the transparent resin 17 in the recessed portion 30a, and bottom portion 30c of the recessed portion 30a under the transparent resin 17 are cut. In the lead-frame sheet 23, the parts located above the wall portions 30b and the parts located above the transparent resin 17 in the recessed portions 30a are cut.

The transparent resin 17 in each recessed portions 30a is cut and thus divided into two segments. The transparent resin 17 in each recessed portion 30a is cut into the two segments each containing at least one LED chip 14. To put it differently, the parts of the transparent resin 17 between the multiple LED chips 14 in each recessed portion 30a are cut.

In FIG. 6B, each part surrounded by dashed lines is one diced semiconductor light-emitting device. By cutting the transparent resin 17 in each recessed portion 30a, the transparent resin 17 is exposed to each of the cutting surfaces.

In the case shown in FIG. 6B, each diced semiconductor light-emitting device has four side surfaces. In three of the four side surfaces, the resin housing 30 coats the transparent resin 17. In the remaining one side surface, the transparent resin 17 is exposed. The top surface of the transparent resin 17 is coated with the parts corresponding to the bottom portions 30c of the recessed portion 30a of the resin housing 30 shown in FIGS. 5A to 5D. Accordingly, the dicing makes it possible to obtain a side-view type semiconductor light-emitting device that emits light through one of the surfaces through which the transparent resin 17 is exposed.

If, as FIG. 7A shows, a single recessed portion 30a is divided into three segments, the semiconductor light-emitting device 61 in the middle of the three has the transparent resin 17 exposed to two opposed side surfaces out of the four side surfaces. That is to say, a side-view type semiconductor light-emitting device capable of emitting light in two opposing directions can be obtained.

Alternatively, each single recessed portion 30a may be divided both in the longitudinal direction and in the widthwise direction. For example, FIG. 7B shows a case where a single recessed portion 30a is divided into six segments. In this case, side-view type semiconductor light-emitting devices 62 in each of which the transparent resin 17 is exposed to three of the four side surfaces can be obtained. In addition, side-view type semiconductor light-emitting devices 63 in each of which the transparent resin 17 is exposed to two side surfaces that are joined together with a corner placed in between.

By the above-described cutting (dicing) process, the dicing regions D shown in FIG. 8 are removed from the lead-frame sheet 23. Hence, the lead-frame sheet 23 is diced into parts in the element regions P. In other words, the lead-frame sheet 23 is cut into the lead frames 11 and the lead frames 12 which are separated from each other.

Moreover, since the parts of the dicing regions D extending in the Y direction pass through the openings 23a in the lead-frame sheet 23, the hanger pin 11d and the hanger pin 11e are formed in each lead frame 11, and the hanger pin 12d and the hanger pin 12e are formed in each lead frame 12.

In addition, the hanger pin 11b and the hanger pin 11c are formed in each lead frame 11 by dividing the corresponding bridge 23b while the hanger pin 12b and the hanger pin 12c are formed in each lead frame 12 by dividing the corresponding bridge 23c.

The leading-end surfaces of the hanger pins 11b to 11e, 12b to 12e are not coated with the transparent resin 17, and exposed to the lower side surfaces of the resin housing 30.

The above-described united body of the lead-frame sheet 23, the transparent resin 17 and the resin housing 30 is cut, for example, from the side of the lead-frame sheet 23. Alternatively, the united body may be cut from the side of the resin housing 30.

Various tests are performed after the dicing. To this end, the leading-end surfaces of the hanger pins 11b to 11e, 12b to 12e can be used as terminals for the testing.

Next, the working/effects of this embodiment will be described below.

The transparent resin 17 coats parts of the bottom surfaces of each lead frame 11 and each lead frame 12, and also coats most of the end surfaces of the lead frame 11 and the lead frame 12. This makes it possible to enhance the retainability of the lead frame 11 and the lead frame 12 while forming the external electrode pads by exposing the bottom surface 11f of the protruding area 11g of the lead frame 11 and the bottom surface 12f of the protruding area 12g of the lead frame 12 from the transparent resin 17.

Specifically, the cutaway part is formed in the two end parts, in the X direction, of the bottom surface of the base portion 11a, and in the two end parts, in the X direction, of the bottom surface of the base portion 12a, by forming the protruding area 11g in the central part, in the X direction, of the base portion 11a, and the protruding area 12g in the central part, in the X direction, of the base portion 12a. The lead frame 11 and the lead frame 12 can be retained firmly by filling the transparent resin 17 into the cutaway portions. This makes the lead frame 11 and the lead frame 12 become less likely to come off the transparent resin 17 in the dicing process, and makes it possible to enhance the yields.

In addition, the silver-plated layers are formed on the top surfaces and the bottom surfaces of the lead frame 11 and the lead frame 12. Because the silver-plated layers have high optical reflectance, the semiconductor light-emitting device of this embodiment is highly efficient in extracting light.

Further, according to this embodiment, a large number of semiconductor light-emitting devices, for example, approximately thousands of semiconductor light-emitting devices can be manufactured from a single conductive sheet 21 en bloc. This makes it possible to reduce manufacturing cost for each semiconductor light-emitting device.

Moreover, the lead-frame sheet 23 is formed by wet etching in this embodiment. Hence, in order to manufacture lead frames with a different layout, only an original plate of the mask needs to be prepared. This makes it possible to reduce the initial costs, compared with a case where the lead-frame sheet 23 is formed by punching with dies.

Furthermore, in this embodiment, the hanger pins extend from the base portion 11a of the lead frame 11, and from the base portion 12a of the lead frame 12. This makes it possible to prevent the base portions themselves from being exposed through the side surfaces of the transparent resin 17, and accordingly to reduce the area of the exposed portion of the lead frame 11 and the area of the exposed portion of the lead frame 12. Consequently, it is possible to prevent the lead frame 11 and the lead frame 12 from coming off the transparent resin 17. In addition, the corrosion of the lead frame 11 and the lead frame 12 can also be reduced.

From a viewpoint of the manufacturing method, these effects are interpreted as follows. In the lead-frame sheet 23, as shown in FIG. 8B, the metal parts existing in the dicing regions D are reduced by providing the openings 23a, the bridges 23b and the bridges 23c passing through the dicing regions D. Accordingly, the dicing becomes easier, and the wearing of the dicing blades can be reduced.

In addition, the four hanger pins extend, in three directions, from each of the lead frame 11 and the lead frame 12. Hence, during the step of mounting the LED chips 14 shown in FIG. 4C, the lead frame 11 in each element region P is supported, securely from three directions, by the lead frames 11 and the lead frame 12 of the respective adjacent element regions P, resulting in better mountability. Likewise, during the wire-bonding step shown in FIG. 4D, too, the bonding position of each wire is supported securely from the three directions. Hence, for example, less of the ultrasonic waves applied when the ultrasonic bonding is done escapes, and accordingly, each wire can be satisfactorily bonded to the corresponding lead frame and the corresponding LED chip.

Additionally, during the dicing step shown in FIG. 5D, the dicing is done from the side of the lead-frame sheet 23. Hence, in the positions where the transparent resin 17 is cut, the metal material forming the cut end parts between the lead frames 11 and the lead frames 12 extends in the +Z direction over the side surfaces of the transparent resin 17. Accordingly, no burrs are produced because the metal material does not extend along the side surfaces of the transparent resin 17 in the −Z direction or stick out from the bottom surface of the transparent resin 17. Consequently, when the semiconductor light-emitting device is packaged, no packaging failure is caused by the burrs.

In addition, the LED chips 14 can be mounted on the lead-frame sheet 23 that has not been coated with the resin housing 30 yet. Furthermore, the LED chips 14 and the corresponding lead frames can be electrically connected to each other by wire bonding. Hence, the work of mounting and wiring chips through narrow openings is not needed any longer. As a consequence, it is possible to enhance the production efficiency, and to reduce the costs.

Besides, the recessed portions 30a are formed in the resin housing 30, the transparent resin 17 is supplied to the recessed portions 30a, the LED chips 14 that are mounted on the lead-frame sheet 23 are pressed onto the transparent resin 17 in the recessed portions 30a, and then the transparent resin 17 is hardened. Hence, no process of introducing the transparent resin through narrow openings is needed. Accordingly, it is possible to enhance the production efficiency, and to reduce the costs.

Moreover, a thin semiconductor light-emitting device can be fabricated easily by making the recessed portions 30a shallower or by making bottom portions 30c of the recessed portions 30a thinner. Neither the forming of the shallower recessed portions 30a nor the forming of the thinner bottom portions 30c of the recessed portions 30a impairs the manufacturing efficiency.

In addition, in this embodiment, the individual semiconductor light-emitting devices are obtained by: uniting the transparent resin 17 and the resin housing 30, en bloc, with the lead-frame sheet 23 where the multiple lead frames 11 and the multiple lead frames 12 are formed; and then dicing the united body thus formed. This makes it possible to enhance the production efficiency, and to increase the efficiency of material use, in comparison to a manufacturing method where the transparent resin and the resin housing are provided to each diced chip and lead frame. Accordingly, this embodiment can provide a thin side-view type semiconductor light-emitting device at lower costs.

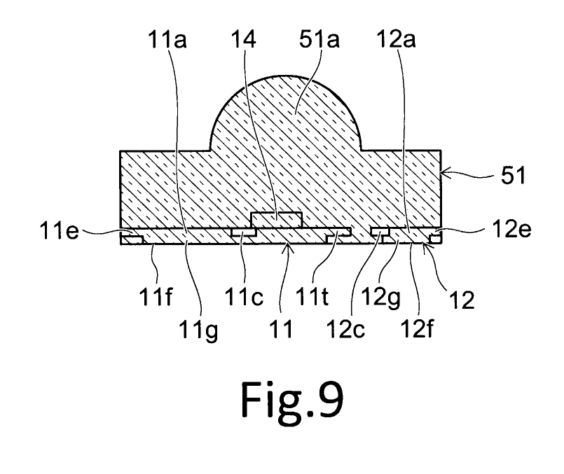

FIG. 9 is a schematic side view of a semiconductor light-emitting device of a second embodiment.

The semiconductor light-emitting device of this embodiment includes an LED chip 14, a lead frame 11 and a lead frame 12 whose constitutions are identical to those of their respective counterparts of the first embodiment shown in FIG. 3. In addition, like in the first embodiment, the terminals of the LED chip 14 are connected to the lead frame 11 and the lead frame 12 by means of the respective wires.

The LED chip 14 is coated with a transparent resin 51. The transparent resin 51 coats most of the lead frame 11 and the lead frame 12. The transparent resin 51 has a convex portion 51a which is provided above the LED chip 14. The bottom surfaces of the lead frame 11 and the lead frame 12 constitute a mounting surface used to mount the semiconductor light-emitting device on a circuit board or the like. The convex portion 51a protrudes in a direction opposite from the mounting surface.

The transparent resin 51 is transparent to light emitted by the LED chip 14. For example, a silicone resin may be used as the transparent resin 51.

The transparent resin 51 coats the top surface of the lead frame 11, the top surface of the lead frame 12, the LED chip 14, and the wires. In addition, the transparent resin 51 is filled into the space between the lead frame 11 and the lead frame 12.

The bottom surface 11f of the protruding area 11g of the lead frame 11 and the bottom surface 12f of the protruding area 12g of the lead frame 12 are not coated with the transparent resin 51, and are thus exposed. The bottom surfaces, respectively, of the lead frame 11 and the lead frame 12, except the bottom surfaces 11f and 12f, are coated with transparent resin 51. To put it differently, part of the transparent resin 17 is exposed to the bottom surfaces of the lead frame 11 and the lead frame 12.

The leading-end surfaces of the hanger pins 11b to 11e, 12b to 12e are exposed without being coated with the transparent resin 51. The top surfaces, the bottom surfaces, and the side surfaces of the hanger pins 11b to 11e, 12b to 12e are coated with the transparent resin 51.

The periphery of the base portion 11a of the lead frame 11 and the periphery of the protruding area 11g are coated with the transparent resin 51. The periphery of the base portion 12a of the lead frame 12 and the periphery of the protruding area 12g are coated with the transparent resin 51. The bottom surface of the thin plate portion 11t of the lead frame 11 and the bottom surface of the thin plate portion 12t of the lead frame 12 are coated with the transparent resin 51.

Only the leading-end surfaces of the hanger pins 11b to 11e, 12b to 12e are exposed to the side surfaces of the transparent resin 51. In addition, only the bottom surface 11f of the protruding area 11g and the bottom surface 12f of the protruding area 12g are exposed from the transparent resin 51 to the bottom surfaces of the lead frame 11 and the lead frame 12.

Like in the first embodiment, a large number of fluorescent bodies may be dispersedly contained in the transparent resin 51. The transparent resin 51 is transparent to light emitted from the fluorescent bodies. The fluorescent bodies are granular, and absorb the light emitted by the LED chip 14, as well as emit light with longer wavelengths.

Next, description will be given below of a method of manufacturing the semiconductor light-emitting device of this embodiment.

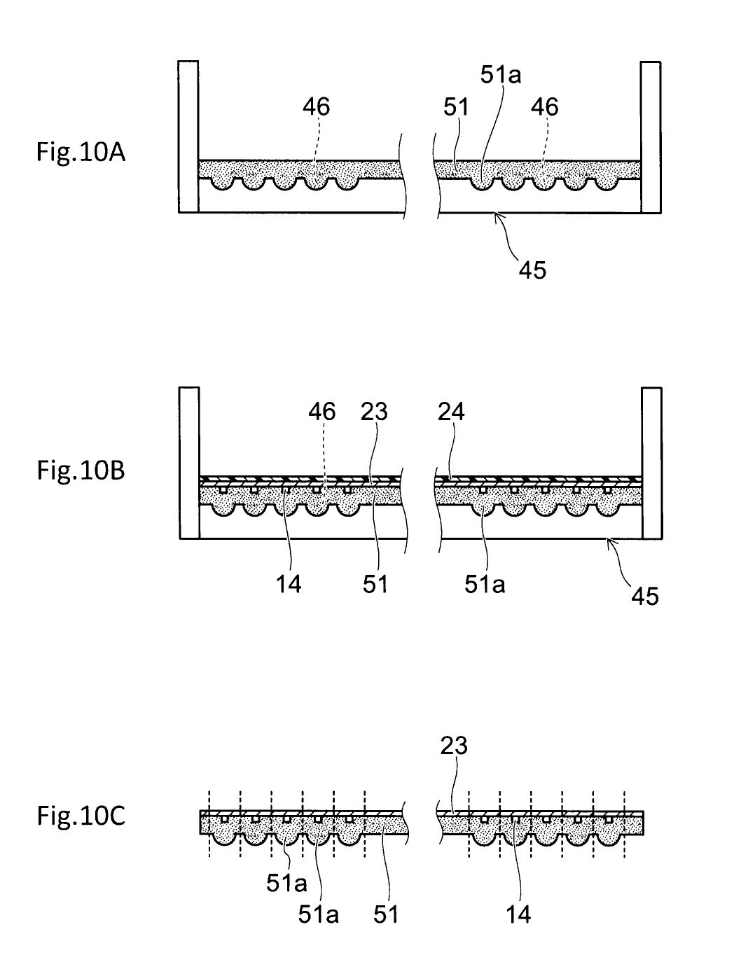

FIGS. 10A to 10D show a process of providing the transparent resin 51 to the lead-frame sheet 23, and a dicing process.

The lead-frame sheet 23 is formed in a similar manner to that which is described in the first embodiment by referring to FIGS. 4A and 4B. The mounting and the wire-bonding of the LED chips 14 on the lead-frame sheet 23 are done also in a similar manner to that which is described in the first embodiment by referring to FIGS. 4C and 4D.

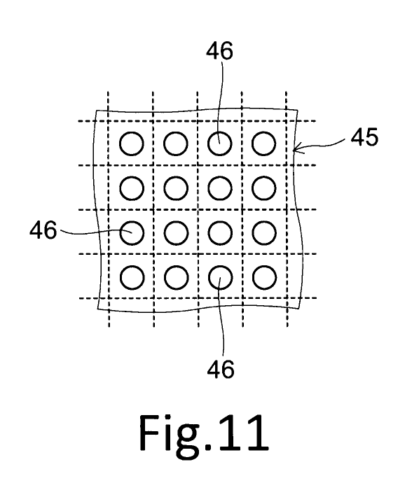

In this embodiment, the compression molding of the transparent resin 51 is performed by using a mold 45 where multiple concave portions 46 are formed as FIG. 10A shows. As the plan view shown in FIG. 11 illustrates, the multiple convex portions 46 are arranged in a matrix shape. When seen from above, the plan shape of each concave portion 46 circular.

As FIG. 10A shows, the transparent resin 51 in an uncured state, such as in a liquid state or in a gel state, is supplied to the concave portions 46. The transparent resin 51 in the liquid state or in a gel state, which contains a fluorescent material, is prepared, for example, by: mixing and agitating the fluorescent material with a transparent resin such as a silicone resin. The transparent resin 51 is also supplied onto the top surfaces of the parts located between adjacent concave portions 46 in the mold 45.

Then, the lead-frame sheet 23 with the LED chips 14 mounted on it is set above the mold 45. The lead-frame sheet 23 is set with the surface, where the LED chips 14 are mounted, faced toward the transparent resin 51 located underneath. The reinforcement tape 24 is applied to the back surface of the lead-frame sheet 23 which is opposite from the surface where LED chips 14 are mounted.

Subsequently, as FIG. 10B shows, the lead-frame sheet 23 is lowered, and is pressed onto the transparent resin 51. The transparent resin 51 coats the LED chip 14, the wires, and the front surface of the lead-frame sheet 23 (the surface where the LED chips 14 are mounted).

At this moment, the transparent resin 51 is filled into the parts of the lead-frame sheet 23 that have been removed by etching. Because the reinforcement tape 24 is applied to the back surface of the lead-frame sheet 23, the transparent resin 51 does not leak out to the back surface of the lead-frame sheet 23. Accordingly, none of the bottom surfaces 11f of the protruding areas 11g of the lead frames 11 and none of the bottom surfaces 12f of the protruding areas 12g of the lead frame 12s are coated with the transparent resin 51.

Then, the transparent resin 51 is hardened with the lead-frame sheet 23 pressed onto the transparent resin 51. The transparent resin 51 is hardened by, for example, heat. In addition, the transparent resin 51 is bonded to the front surfaces of the lead frames 11 and the front surfaces of the lead frames 12. Consequently, the lead-frame sheet 23 and the transparent resin 17 are integrally united together.

Thereafter, the united body of the lead-frame sheet 23 and the transparent resin 51 is taken out of the mold 45. Afterward, the reinforcement tape 24 is peeled off. Thus, the bottom surfaces 11f of the protruding areas 11g of the lead frames 11 and the bottom surfaces 12f of the protruding areas 12g of the lead frames 12 are exposed to the back surface of the lead-frame sheet 23.

Subsequently, the lead-frame sheet 23 and the transparent resin 51 are cut by using, for example, blades. The cutting is done along the dashed lines shown in FIG. 10C. In FIG. 11, the cutting positions seen from above are indicated with dashed lines.

The transparent resin 51 is cut in the parts each of which is located between two adjacent convex portions 51a formed by filling the concave portions 46 of the mold 45 with the transparent resin 51. Hence, each diced semiconductor light-emitting device includes one convex portion 51a.

In FIG. 11, each part surrounded by dashed lines becomes a diced semiconductor light-emitting device. Each semiconductor light-emitting device includes at least one the LED chip 14. All the parts of the transparent resin 51 on the lead frame 11 and the lead frame 12 are exposed.

In this embodiment, the concave portions 46 are formed in the bottom of the mold 45, and the transparent resin 51 is supplied to the concave portions 46. Then, the lead-frame sheet 23 where the LED chips 14 are mounted is pressed onto the transparent resin 51, and thereby the transparent resin 51 is compression-molded. Thus, a lens-top type semiconductor light-emitting device can be manufactured easily.

Although the concave shape that enables a lens to be formed has been cited as an example of the pattern shape formed in the bottom of the mold 45, any shape may be employed as long as the necessary optical properties can be obtained from the employed shape.

In this embodiment, too, the individual semiconductor light-emitting devices are obtained by uniting the transparent resin 51, en bloc, with the lead-frame sheet 23 where the multiple lead frames 11 and the multiple lead frames 12 are formed; and dicing the united body thus formed. This makes it possible to enhance the production efficiency, and to increase the efficiency of material use, as well as to provide a semiconductor light-emitting device at low costs, in comparison to a manufacturing method where the transparent resin is provided to each diced chip and lead frame.

This embodiment prevents the resin housing from deteriorating due to its absorption of light and heat produced by the LED chip 14, because no resin housing or packaging member that surrounds the transparent resin 51 is provided. Although, in particular, the deterioration of the resin housing tends to progress rapidly in a case where the resin housing is made of a polyamide thermoplastic resin, this embodiment is immune from such deterioration. Accordingly, the semiconductor light-emitting device of this embodiment has excellent durability. Consequently, the semiconductor light-emitting device of this embodiment has a long service life, is highly reliable, and has a wide variety of use applications. In addition, because the semiconductor light-emitting device of this embodiment is provided with no resin housing, the parts and manufacturing steps are smaller in number, and the costs are lower.

In addition, the transparent resin 51 is made of a silicone resin. Because the silicone resin is highly durable against light and heat, this durability enhances the durability of the semiconductor light-emitting device as well.

In addition, because no resin housing that coats the side surfaces of the transparent resin 51 is provided, light is emitted at wider angles. Hence, the semiconductor light-emitting device of this embodiment is advantageous for an application requiring light to be emitted at wider angles, for example, when used as a light and the backlights for a liquid crystal television.

Like in the first embodiment, the transparent resin 51 of this embodiment coats part of the bottom surface of each lead frame 11 and part of the bottom surface of each lead frame 12, as well as most of the end surfaces of the lead frame 11 and most of the end surfaces of the lead frame 12. This makes it possible to enhance the retainability of the lead frame 11 and the lead frame 12 while realizing the external electrode pads by exposing the bottom surface 11f of the protruding area 11g of the lead frame 11 and the bottom surface 12f of the protruding area 12g of the lead frame 12 from the transparent resin 51.

Specifically, the cutaway part is realized in the two end parts, in the X direction, of the bottom surface of the base portion 11a, and in the two end parts, in the X direction, of the bottom surface of the base portion 12a, by forming the protruding area 11g in the central part, in the X direction, of the base portion 11a, and the protruding area 12g in the central part, in the X direction, of the base portion 12a. The lead frame 11 and the lead frame 12 can be retained firmly by filling the transparent resin 51 into the cutaway portions. This makes the lead frame 11 and the lead frame 12 become less likely to come off the transparent resin 51 in the dicing process, and makes it possible to enhance the yields.

Furthermore, in this embodiment, too, the hanger pins extend from the base portion 11a of the lead frame 11, and from the base portion 12a of the lead frame 12. This makes it possible to prevent the base portions themselves from being exposed to the side surfaces of the transparent resin 51, and accordingly to reduce the area of the exposed part of the lead frame 11 and the area of the exposed part of the lead frame 12. Consequently, it is possible to prevent the lead frame 11 and the lead frame 12 from coming off the transparent resin 51. In addition, the corrosion of the lead frame 11 and the lead frame 12 can also be reduced.

Additionally, in the dicing step shown in FIG. 10C, the dicing is done from the side of the lead-frame sheet 23. Hence, the metal material forming the cut end parts between the lead frames 11 and the lead frames 12 extends in the +Z direction over the side surfaces of the transparent resin 17. Accordingly, no burrs are produced because the metal material does not extend along the side surfaces of the transparent resin 17 in the −Z direction or stick out from the bottom surface of the transparent resin 17. Consequently, when the semiconductor light-emitting device is packaged, no packaging failure is caused by the burrs.

In the embodiments described above, the structure of each LED chip 14 is not limited to the structure where the two terminals are provided on the top surface of the LED chip 14. Instead, a structure may be used in which: one of the two terminals is provided on the bottom surface of the LED chip 14; and that one of the two terminals is bonded to one of the two lead frames by the face-down bonding technique. Alternatively, a structure may be used in which: both of the two terminals are provided on the bottom surface of each LED chip 14; the two terminals are bonded to the first lead frame 11 and the second lead frame 12, respectively, by the face-down bonding technique. In addition, multiple LED chips 14 may be mounted on each semiconductor light-emitting device.

In addition, a third lead frame, which is flush with and separated from the first lead frame 11 and the second lead frame 12, may be provided between the first lead frame 11 and the second lead frame 12 with the LED chip 14 mounted on the third lead frame. In this case, the third lead frame can be made to function as a heat sink instead of an electrode.

Furthermore, each LED chip 14 is not necessarily a chip that emits blue light. The fluorescent material is not necessarily a fluorescent material that absorbs blue light and emits yellow light. Each LED chip 14 may be that which emits visible light of any color other than blue, or may be that which emits UV light or infrared light. The fluorescent material may be that which emits blue light, green light or red light.

Moreover, the color of the light that is emitted by the semiconductor light-emitting device as a whole is not limited to white. Light of any color tone can be created by adjusting an R:G:B weight ratio among a red-color fluorescent material, a green-color fluorescent material and a blue-color fluorescent material. For example, the white light in a range of the color of the white lamp to the color of the white fluorescent lamp can be created by setting the R:G:B ratio at any of the following ranges: 1:1:1 to 7:1:1; 1:1:1 to 1:3:1; and 1:1:1 to 1:1:3. In addition, the transparent resin may contain no fluorescent material at all. In this case, the semiconductor light-emitting device emits the light emitted by the LED chip 14.

While certain embodiments have been described, these embodiments have been presented by way of examples only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light-emitting device comprising:
a lead frame including a first lead frame and a second lead frame that are placed on a single plane and are separated from each other;
a light-emitting element mounted on a top surface of the lead frame, and including a first terminal connected to the first lead frame and a second terminal connected to the second lead frame;
a transparent resin coating the light-emitting element and the top surface of the lead frame, and filled in a space between the first lead frame and the second lead frame, a part of the transparent resin being exposed to a bottom surface of the lead frame; and
a resin housing provided on the lead frame, and including an upper part coating a top surface of the transparent resin, side-surface parts coating side surfaces of the transparent resin, and an opening through which one of the side surfaces of the transparent resin is exposed.

2. The semiconductor light-emitting device according to claim 1, wherein at least an internal wall of the resin housing has reflectivity to light emitted by the light-emitting element.

3. The semiconductor light-emitting device according to claim 2, wherein the transparent resin contain fluorescent bodies.

4. The semiconductor light-emitting device according to claim 2, wherein
protruding areas are formed in a bottom surface of the first lead frame and a bottom surface of the second lead frame, respectively,
bottom surfaces of the protruding areas are exposed without being coated with the transparent resin, and
side surfaces of the protruding areas are coated with the transparent resin.

5. The semiconductor light-emitting device according to claim 4, wherein at least one of the first and the second lead frames includes:
a base portion whose periphery is coated with the transparent resin; and
a hanger pin extending from the base portion, a bottom surface of the hanger pin being coated with the transparent resin.

6. The semiconductor light-emitting device according to claim 5, wherein a leading-end surface of the hanger pin extending from the base portion is exposed without being coated with the transparent resin.

7. A method of manufacturing a semiconductor light-emitting device comprising the steps of:
supplying uncured transparent resin to a recessed portion of a resin housing;
mounting a light-emitting element on a first surface of a lead-frame sheet including a first lead frame and a second lead frame which are placed on a single plane and are separated from each other, then hardening the transparent resin with the first surface, where the light-emitting element is mounted, dipped in the transparent resin; and
after hardening the transparent resin, cutting a wall part of the recessed portion of the resin housing, the transparent resin in the recessed portion, and the lead-frame sheet and a bottom part of the recessed portion under the transparent resin.

8. The method of manufacturing a semiconductor light-emitting device according to claim 7, comprising the steps of:
supplying uncured transparent resin to a recessed portion of a resin housing;
mounting a light-emitting element on a first surface of a lead-frame sheet including a first lead frame and a second lead frame which are placed on a single plane and are separated from each other, then hardening the transparent resin with the surface, where the light-emitting element is mounted, dipped in the transparent resin while a second surface of the lead frame sheet is supported by a support member;
after hardening the transparent resin, removing the support member; and
after hardening the transparent resin, cutting a wall part of the recessed portion of the resin housing, the transparent resin in the recessed portion, and the lead-frame sheet and a bottom part of the recessed portion under the transparent resin.

9. The method of manufacturing a semiconductor light-emitting device according to claim 8, wherein the recessed portion of the resin housing is formed by using a mold having a recessed part.

10. The method of manufacturing a semiconductor light-emitting device according to claim 9, wherein the mold has recessed parts arranged in a matrix pattern.

11. The method of manufacturing a semiconductor light-emitting device according to claim 9, wherein a part of the transparent resin between portions filled in the recessed parts of the mold is cut.

12. The method of manufacturing a semiconductor light-emitting device according to claim 8, wherein fluorescent bodies are mixed in the uncured transparent resin.

13. The method of manufacturing a semiconductor light-emitting device according to claim 7, wherein
the step of forming the lead-frame sheet includes a step of forming protruding areas in a bottom surface of the first lead frame and a bottom surface of the second lead frame by: selectively etching the conductive sheet from the top surface and from the bottom surface of the conductive sheet; and then stopping at least the etching from the bottom surface before the etching penetrates the conductive sheet, and
once the support member is removed, the bottom surfaces of the protruding areas are exposed from the transparent resin.
